(19) United States
(12) Patent Application Publication
(10) Pub. No.: US 2005/0253233 A1
(43) Pub. Date: Nov. 17, 2005

(54) Power module and electric transportation apparatus incorporating the same

(76) Inventors: Takayuki Murai, Shizuoka (JP); Koji Morita, Shizuoka (JP)

Correspondence Address: KEATING & BENNETT, LLP, 8180 GREENSBORO DRIVE, SUITE 850, MCLEAN, VA, 22102, US

(21) Appl. No.: 11/113,079

(22) Filed: Apr. 22, 2005

(30) Foreign Application Priority Data
Apr. 28, 2004 (JP) 2004-132778

(51) Int. Cl. H01L 23/02

(52) U.S. Cl. 257/678

(57) ABSTRACT

A power module includes a substrate having an insulative surface and a conductive pattern disposed on the insulative surface, a semiconductor device disposed on the substrate, a plate conductor provided on the conductive pattern with an insulating layer interposed therebetween, and a wire arranged to electrically connect the plate conductor and the semiconductor device.

### BACKGROUND OF THE INVENTION

1. Field of the Invention

The present invention relates to a power module and an electric transportation apparatus including the same. More particularly, the present invention relates to a power module for supplying power to a motor which is used as a driving mechanism of a transportation apparatus, and an electric transportation apparatus including such a power module.

2. Description of the Related Art

In recent years, transportation apparatuses which utilize an electric motor (hereinafter simply referred to as a “motor”) as a driving mechanism have been drawing attention, due to concerns of environmental or energy issues, etc. As compared to an internal combustion engine, a motor permits a great amount of design freedom in its outer shape, thus enabling the motor to be installed close to a driving mechanism. A motor is also advantageous in that it produces little operating noise while being operated. Therefore, with a motor, it is possible to realize a novel transportation apparatus having features which do not pertain to transportation apparatuses incorporating conventional internal combustion engines. From such perspectives, development activities are being directed to transportation apparatuses incorporating motors.

A transportation apparatus incorporating a motor includes a power module (a power semiconductor apparatus) which supplies power to the motor and controls the revolutions of the motor. FIG. 1 is a circuit diagram disclosed in Japanese Laid-Open Patent Publication No. 2002-262593, in which a conventional power module is included. As shown in FIG. 1, power which is supplied from the battery 12 is converted to an appropriate driving power by a power module 10 shown by a broken line, and supplied to the motor 14. As shown in FIG. 1, the power module 10 includes a speed control circuit 20, a smoothing capacitor 22, a plurality of FETs (field-effect transistors) 16, and a plurality of diodes 18.

FIGS. 2A and 2B are, respectively, a plan view and a side view showing the power module 10, whose component elements other than the speed control circuit 20 are formed on a printed wiring board. As shown in FIGS. 2A and 2B, the power module 10 includes a printed wiring board 40, having a surface on which conductive regions 40a, 40b, 40c, and 40d are formed. The conductive region 40c includes a plurality of subregions, with resistors being connected between subregions.

FETs and diodes which are used in such a power module are likely to increase in temperature due to a large current flowing therethrough. In order to avoid failure, such elements need to have a high heat-releasing ability. Therefore, FETs and diodes for use in a power module are structured so as to be directly bonded to the conductive pattern surface of the circuit board, in order to realize good heat-releasing characteristics.

Specifically, each FET 16 is soldered to the conductive pattern 40b so that its drain electrode is in contact with the conductive pattern 40b. A gate electrode of each FET 16 is connected to a conductive pattern 40c via a wire 42b composed of aluminum. A source electrode of each FET 16 is connected to the conductive pattern 40d via two wires 42a. Furthermore, a source electrode of each FET 16 is connected to the conductive pattern 40c via a wire 42c. On the other hand, each diode 18 is soldered to the conductive pattern 40a so that its cathode electrode is in contact with the conductive pattern 40a. An anode electrode of each diode 18 is connected to the conductive pattern 40b via wires 41a composed of aluminum.

In the power module shown in FIGS. 2A and 2B, a large current flows through the conductive pattern 40b, to which the FETs 16 are soldered. Therefore, it is necessary to broaden the width of the conductive pattern 40b so as to reduce the resistance of the conductive pattern 40b. However, doing so will require an increase in the length of the wires 42a connected to the FETs 16, which in turn will cause heating problems associated with the wire resistance. For example, if three wires each having a diameter of 0.5 mm and a length of 15 mm are connected in a parallel connection, there is a wire resistance of 0.7 mΩ across the two ends of the parallel connection. If a current of 100 A is flowed between these two end, a heat of 7.0 W is generated in the wires, so that the wires may reach a temperature of 200° C. or more, for example. The generated heat is transmitted to the FETs 16, thus increasing the temperature of the FETs 16. Thus, the maximum large current value which can be flowed through the power module is limited to a value which will not invite a degree of heating such that the wires 42a and the FETs 16 are deteriorated.

In theory, heating of the wires 42a may be counteracted in several ways. For example, the number of wires connecting each FET 16 to a conductive region may be increased to reduce resistance, thus minimizing the amount of generated heat. However, the number of wires that can be connected to an FET 16 is limited by the size of each electrode of the FET 16, and thus it is impossible to connect too many wires to an electrode. Moreover, ultrasonic waves are used for the wire connecting process. Any increase in the number of wires or the wire thickness will result in an increased bonding area, and consequently, the ultrasonic waves may damage the FETs, possibly reducing the reliability of the FETs.

It may be possible to use two conductive layers for the printed wiring board, thus to increase the layout flexibility of the conductive regions, the FETs and diodes on the printed wiring board. In this manner, each electrode of each FET may be placed close to a conductive pattern, thus reducing the length of the wire connecting the electrode to the conductive pattern. However, in this case, it also becomes necessary to provide an insulating layer for the printed wiring board in order to realize insulation between the two conductive layers. Since an insulating layer generally has a poor thermal conductivity, the addition of the insulating layer will result in a reduced heat-releasing ability of the printed wiring board, thus lowering the efficiency with which the heat generated in the FETs and wires is dissipated to the exterior via the printed wiring board.

Alternatively, it may be possible to use a printed wiring board with a single thick conductive layer, thus to reduce the width of any conductive pattern across which a wire must be extended. In this case, however, the thickness of the conductive layer may make it difficult to perform patterning by etching or the like.

### SUMMARY OF THE INVENTION

In order to overcome the problems of conventional power modules described above, preferred embodiments of the present invention provide a power module which does not induce much heating, and which is thus reliable or capable of allowing a large current to be flowed therethrough.

A power module according to a preferred embodiment of the present invention includes a substrate having an insulative surface and including a conductive pattern disposed on the insulative surface, a semiconductor device disposed on the substrate, a plate conductor provided on the conductive pattern with an insulating layer interposed therebetween, and a wire arranged to electrically connect the plate conductor and the semiconductor device.

In a preferred embodiment, the conductive pattern includes first, second, and third conductive regions, and a portion of the plate conductor is placed above the second conductive region with the insulating layer interposed therebetween, and another portion of the plate conductor is electrically connected to the third conductive region.

In a preferred embodiment, the first, second, and third conductive regions are arranged in such a manner that the second conductive region is interposed between the first and third conductive regions. Any conductive region other than the second conductive region may be present between the first and third conductive regions.

In a preferred embodiment, the semiconductor device has first and second principal surfaces, and includes a first pad provided on the first principal surface and a second pad provided on the second principal surface, the semiconductor device is disposed on the first conductive region, the first pad of the semiconductor device opposes and is electrically connected to the first conductive region, and the wire is electrically connected to the second pad.

In a preferred embodiment, the other portion of the plate conductor is soldered to the third conductive region, and the first pad of the semiconductor device is soldered to the first conductive region.

In a preferred embodiment, the plate conductor is preferably composed mainly of copper, and is surface-treated to have increased solder wettability at least in a region which is soldered to the third conductive region.

In a preferred embodiment, the wire is composed mainly of aluminum.

In a preferred embodiment, the wire is bonded to the second pad and the plate conductor by ultrasonic waves.

In a preferred embodiment, the wire is a flexible thin line having two ends and an intermediate portion, the two ends being bonded to the plate conductor, and the intermediate portion being bonded to the second pad.

In a preferred embodiment, the power module includes a plurality of wires for connecting the plate conductor and the second pad.

In a preferred embodiment, the semiconductor device is a field-effect transistor.

In a preferred embodiment, the power module includes a plurality of the semiconductor devices and a plurality of the plate conductors.

In a preferred embodiment, the substrate includes a metal substrate and an insulating layer disposed on a surface of the metal substrate.

An electric transportation apparatus according to another preferred embodiment of the present invention includes any of the aforementioned power modules, and a motor electrically connected to the power module.

An electric vehicle according to a further preferred embodiment of the present invention includes any of the aforementioned power modules, a motor electrically connected to the power module, a battery for supplying power to the power module, and a wheel to be driven by the motor.

A production method for producing a power module according to yet another preferred embodiment of the present invention includes the steps of preparing a substrate having a conductive pattern provided on a surface thereof, affixing by soldering a semiconductor device onto the substrate, and affixing by soldering a plate conductor onto the conductive pattern with an insulating layer interposed between the plate conductor and the conductive pattern, and connecting the plate conductor and the semiconductor device via a conductive wire.

A connection method according to another preferred embodiment of the present invention for connecting two conductive regions with a conductive wire includes the steps of causing a first end of a flexible conductive wire having first and second ends and an intermediate portion interposed between the first and second ends to be bonded to a first conductive region by ultrasonic waves, causing the intermediate portion of the conductive wire to be bonded to the second conductive region by ultrasonic waves, and causing the second end of the conductive wire to be bonded to the first conductive region by ultrasonic waves.

In accordance with a power module of a preferred embodiment of the present invention, the heat which is generated due to a current flowing between a conductive pattern and a semiconductor device (e.g., a transistor) on a substrate is reduced. As a result, any increase in the temperature of the semiconductor device is prevented, thus improving reliability and allowing a greater current to be flowed through the power module.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a circuit diagram showing a motor controller including a conventional power module.

FIGS. 2A and 2B are a plan view and a side view, respectively, showing the conventional power module of FIG. 1.

FIG. 3 is a circuit diagram schematically showing a driving system including a power module according to a preferred embodiment of the present invention.

FIG. 4 is a plan view showing a power module according to a preferred embodiment of the present invention.

FIG. 5 is an enlarged cross-sectional view showing a portion of the power module of FIG. 4.

FIGS. 6A and 6B are a plan view and a side view, respectively, showing a transistor to be used in the power module of FIG. 4.

FIG. 7 is a cross-sectional view showing a structure in which a transistor is connected to a conductive pattern only via wires as in conventional techniques.

FIGS. 8A and 8B are a plan view and a cross-sectional view, respectively, showing a bonding wire structure according to a preferred embodiment of the present invention.

FIGS. 9A and 9B are a plan view and a cross-sectional view, respectively, showing a conventional bonding wire structure.

FIG. 10 is a diagram showing a procedure for forming a bonding wire structure according to a preferred embodiment of the present invention.

FIG. 11 is another diagram showing a procedure for forming a bonding wire structure according to a preferred embodiment of the present invention.

FIG. 12 is still another diagram showing a procedure for forming a bonding wire structure according to a preferred embodiment of the present invention.

FIG. 13 is a diagram illustrating an electric vehicle according to a preferred embodiment of the present invention.

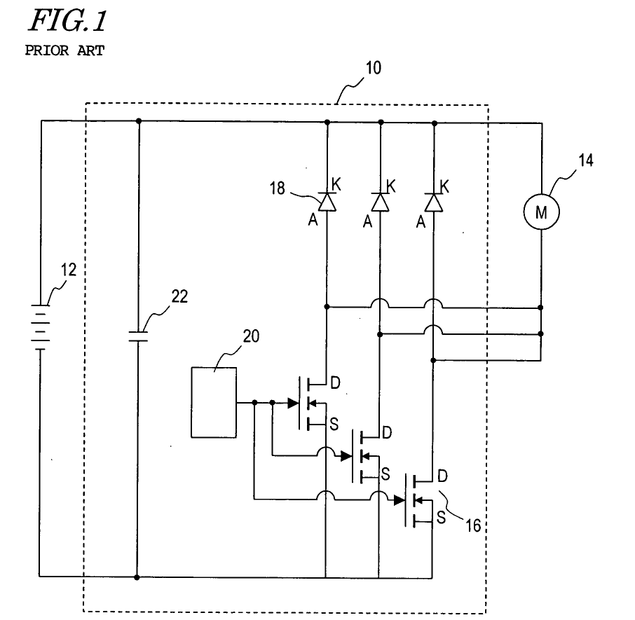

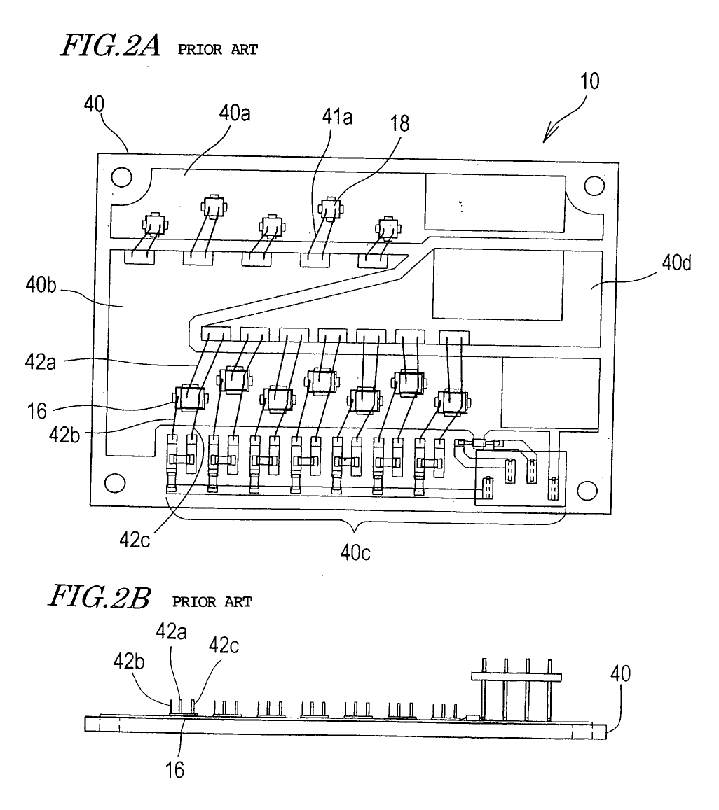

### DETAILED DESCRIPTION OF PREFERRED EMBODIMENTS

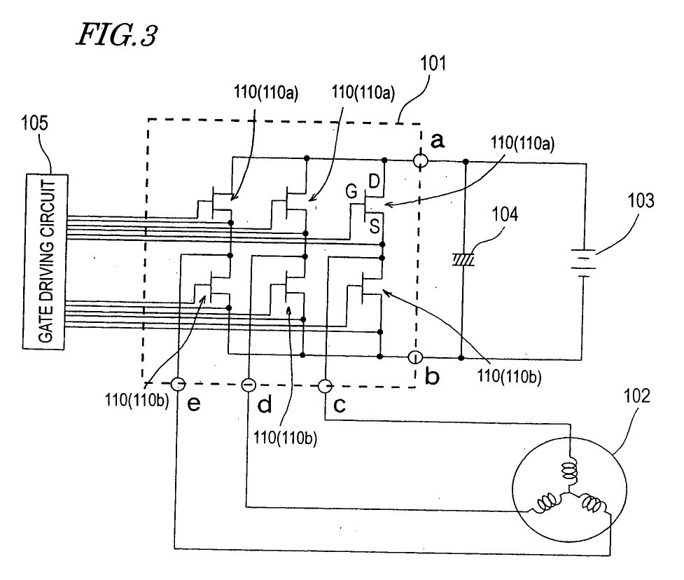

Hereinafter, preferred embodiments of the present invention will be described with reference to the accompanying drawings. FIG. 3 is a circuit diagram schematically showing a driving system of a transportation apparatus incorporating a power module according to one preferred embodiment of the present invention. The power module of the present invention can be used in a variety of transportation apparatuses which utilize a motor as a driving mechanism. In the present specification, the term “wiring” or “wiring elements” is not limited only to traditional wires, but rather is used to broadly encompass any other means of electrical connection.

As shown in FIG. 3, the transportation apparatus comprises a power module 101, a motor 102, a battery 103, a smoothing capacitor 104, and a gate driving circuit 105. In the present preferred embodiment, the motor 102 is preferably a brush-less DC motor. To the three terminals of the motor 102, a three-phase current having phases which are 1200 apart from one another is applied, whereby the motor 102 is driven.

The battery 103 is connected in parallel to the smoothing capacitor 104 for smoothing out voltage fluctuations, and connected to terminals a and b of the power module 101 in order to supply power to the power module 101. The power module 101 receives DC voltage power from the battery 103, and generates driving power which is suitable for driving the motor 102. Since the motor 102 is to be driven with a three-phase current, the power module 101 generates a three-phase current from the DC current. For this purpose, between the terminals a and b of the power module 101, three current paths are formed, each of which is composed of a series connection of two field-effect transistors 110a and 110b. In other words, the power module 101 preferably includes six field-effect transistors 110 as power semiconductor devices (i.e., semiconductor devices for performing switching operation for controlling the current supply).

Although the present preferred embodiment illustrates an example where MOS type field-effect transistors (hereinafter simply referred to as “transistors”) are preferably used as the power semiconductor devices (switching elements), bipolar transistors or any other transistors may instead be used as the power semiconductor devices. Other than transistors, any power semiconductor devices capable of allowing a large current to be applied thereto, e.g., diodes or thyristors, may also be used.

To a gate electrode of each transistor 110, a control signal which is generated by the gate driving circuit 105 is applied, on the basis of which each transistor 110 performs switching operations. Each transistor 110 is rapidly switched with a frequency based on pulse width modulation (PWM), whereby a three-phase current is generated and applied to the motor 102 via the terminals c, d, and e.

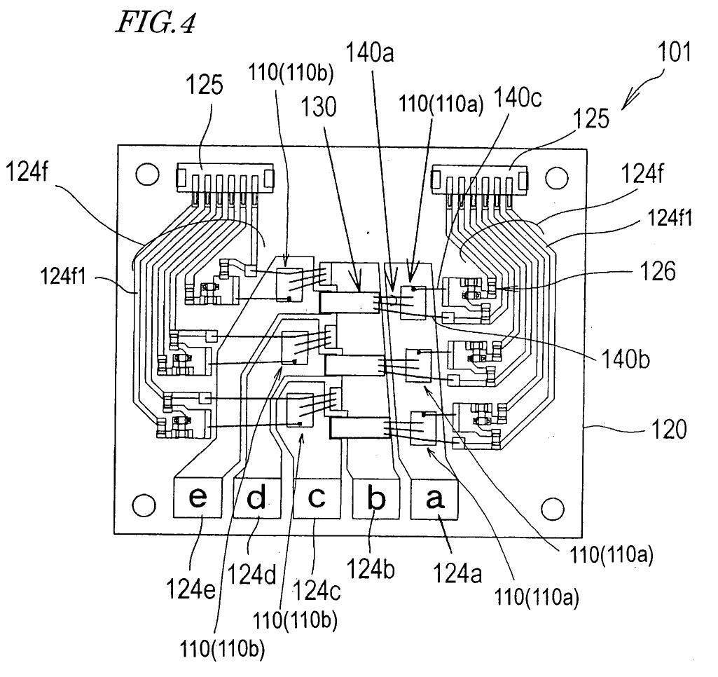

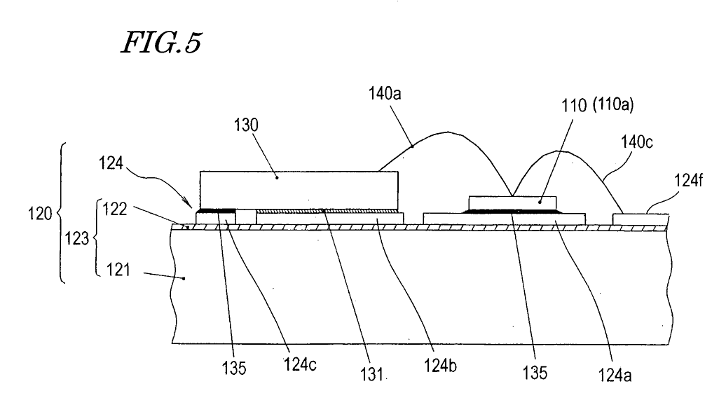

FIG. 4 is a plan view of the power module 101 as constructed on a circuit board. FIG. 5 is a partially-enlarged cross-sectional view thereof. The power module 101 preferably includes a wiring board 120, the transistors 110, a plate conductor 130, and wires 140a, 140b, and 140c. The plate conductor 130 has a greater cross-sectional area, and hence a lower electrical resistance, than that of each wire 140a.

The wiring board 120 includes a substrate 123 having an insulative surface, and a conductive pattern 124 provided on the insulative surface. In the power module 101, a substantial heat may be generated when a large current, e.g. 50 A or more, flows through the transistors 110 or any wiring elements. Therefore, it is preferable that the substrate 123 has a good thermal conductivity for allowing the generated heat to be dissipated to the exterior of the power module 101 via the substrate 123. For example, the substrate 123 may be composed of a base substrate 121 (mainly aluminum) and an insulating layer 122 (epoxy resin or polyimide film) formed on the surface of the base substrate 121. In this case, since the insulating layer 122 generally has a low thermal conductivity, it is preferable to reduce the thickness of the insulating layer 122 so as to be just thick enough to realize electrical insulation, while making the base substrate 121 sufficiently thick for securing the strength of the wiring board 120. From the standpoints of thermal conductivity and structural strength, a metal substrate is preferably used as the base substrate 121. Alternatively, a thin plate composed of a material having good insulation and thermal conductivity may be used as the substrate 123.

The conductive pattern 124 formed on the insulative surface of the substrate 123 preferably includes a first conductive region 124a, a second conductive region 124b, a third conductive region 124c, a fourth conductive region 124d, a fifth conductive region 124e, and a sixth conductive region 124f. One end of the first conductive region 124a constitutes a terminal a; one end of the second conductive region 124b constitutes a terminal b; one end of the third conductive region 124c constitutes a terminal c; one end of the fourth conductive region 124d constitutes a terminal d; and one end of the fifth conductive region 124e constitutes a terminal e.

To the first conductive region 124a and the second conductive region 124b, plus and minus voltages are respectively applied from the battery 103. A driving current for driving the motor 102 flows in the third conductive region 124c, the fourth conductive region 124d, and the fifth conductive region 124e. These conductive regions have a sufficient width (e.g., about 3 mm to about 30 mm) for allowing a large current to flow therethrough, and a thickness of about 0.05 mm to about 0.7 mm, for example. The sixth conductive region 124f includes a plurality of thin-line regions 124f1 which are connected to the source or gate of each transistor 110. The thin-line regions 124f1 are also electrically connected to connectors 125 for providing connection to the gate driving circuit 105 (FIG. 3). Chip resistors 126 are soldered between thin-line regions 124f1. Specifically, one chip resistor 126 is connected to the gate of each transistor 110, and another chip resistor 126 is connected between the gate and the source of each transistor 110.

Note that the conductive pattern 124 shown in FIG. 4 is only exemplary. A conductive pattern 124 which is patterned in any shape other than that exemplified in FIG. 4 may instead be formed on the substrate 123.

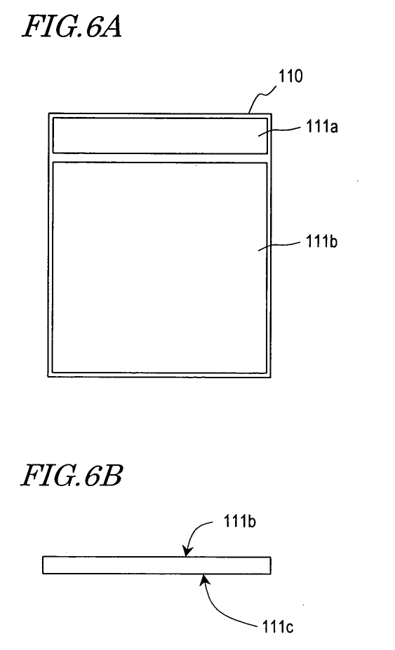

FIGS. 6A and 6B are a plan view and a side view, respectively, showing each transistor 110. The transistor 110 has first and second principal surfaces, and includes a first pad 111a located on the first principal surface, and a second pad 111b and a third pad 111a located on the second principal surface. These pads 111a, 111b and 111a are electrically connected to the gate, source, and drain of the transistor. For example, the first pad 111a may be a drain pad (drain electrode) connected to the drain, whereas the second pad 111b and the third pad 111a may be a source pad (source electrode) and a gate pad (gate electrode) which are connected to the source and the gate, respectively.

As shown in FIGS. 4 and 5, three transistors 11a among the six transistors 110 are arranged on the first conductive region 124a, in such a manner that the first pad 111c of each transistor 110a opposes the first conductive region 124a so as to achieve electrical connection between the first pad 111c (FIG. 6B) and the first conductive region 124a. The first pads 111c of the transistors 110a are connected to the first conductive region 124a preferably via solder 135.

The other three transistors 11b are arranged on the third, fourth, and fifth conductive regions 124c, 124d, and 124e, in such a manner that the first pad 111c of each transistor 110b opposes the corresponding conductive region so as to achieve electrical connection between the first pad 111c and the conductive region preferably via solder 135.

In the conductive pattern 124 shown in FIG. 4, the second conductive region 124b is interposed between the first conductive region 124a (on which the transistors 110a are placed) and the third, fourth, and fifth conductive regions 124c, 124d, and 124e (on which the transistor 110b is placed). Therefore, in order to make any electrical connection between each pair of transistors 110a and 110b constituting a current path, the connection is preferably adjacent to the second conductive region 124b.

Each of the three plate conductors 130 is arranged in such a manner that a portion thereof lies on the second conductive region 124b, while another portion lies on the third, fourth, or fifth conductive region 124c, 124d, or 124e. Each plate conductor 130 opposes the second conductive region 124b with an insulating layer 131 interposed therebetween for preventing electrical connection between the plate conductor 130 and the second conductive region 124b. On the other hand, each plate conductor 130 is soldered to the third, fourth, or fifth conductive regions 124c, 124d, or 124e preferably via solder 135, thus establishing electrical connection between the plate conductor 130 and each conductive region.

In the present preferred embodiment as illustrated in FIG. 4, each of the three plate conductors 130 is arranged in such a manner that a portion thereof lies on the second conductive region 124b, while another portion lies on the third, fourth, or fifth conductive region 124c, 124d, or 124e. However, depending on the shape of the conductive pattern, each plate conductor 130 may include portions which lie on two or more conductive regions (with an insulating layer interposed between the plate conductor 130 and any such conductive region), and a portion which is electrically connected to another conductive region. For example, in the conductive pattern 124 as shown in FIG. 4, a seventh conductive region may further be provided between the first conductive region 124a and the second conductive region 124b, so that the three plate conductors 130 each extend to the seventh conductive region astride the second conductive region 124b. Alternatively, in the conductive pattern 124 as shown in FIG. 4, a seventh conductive region may further be provided between the second conductive region 124b and the third, fourth, and fifth conductive regions 124c, 124d, and 124e, so that the three plate conductors 130 extend to the second conductive region 124b astride the seventh conductive region. In either case, an insulating layer 131 is to be provided between the seventh conductive region and each of the three plate conductors 130.

The plate conductors 130 preferably have only a small resistance. For example, the plate conductors 130 may be composed of a conductor which mainly contains (typically about 95% or more of) copper, aluminum, or other suitable material. It is preferable that the region of each plate conductor 130 to be soldered to the third, fourth, or fifth conductive regions 124c, 124d, or 124e has good solder wettability. For example, this region of each plate conductor 130 is preferably subjected to a surface treatment for improving solder wettability, e.g., solder plating, tin plating, nickel plating, or gold flash plating. As will be described later, the region of each plate conductor 130 to be connected to a wire is preferably subjected to a surface treatment such as nickel plating or gold flash plating in order to ensure good wire connection. The shape and thickness of each plate conductor 130 may be designed so as to optimize the resistance value and the amount of generated heat of the plate conductor 130. From the standpoint of facilitating the realization of a sufficiently small resistance value, the plate conductor 130 preferably has a thickness of no less than about 0.5 mm, and more preferably has a thickness of no less than about 1.0 mm, for example.

The insulating layers 131 are preferably composed of an insulative material, e.g., an epoxy resin or polyimide film. Alternatively, the insulating layer 131 may be air as long as an interspace between each plate conductor 130 and the second conductive region 124b can be secured simply by soldering the plate conductor 130 to the third, fourth, or fifth conductive regions 124c, 124d, or 124e, for example.

Each plate conductor 130, one of whose ends is connected to a transistor 110a via wires 140a, functions as a conductive connection mechanism to electrically connect the transistor 110a to the conductive pattern 124c, 124d, or 124e on the wiring board 120. In order to minimize the length of each wire 140a, which inevitably has a relatively large resistance, it is preferable that the aforementioned end of each plate conductor 130 is located as close to the corresponding transistor 110a as possible.

The wires 140a, 140b, and 140c are used for electrically connecting the second pad 111b (FIGS. 6A and 6B) and the third pad 111a (FIG. 6A) of each transistor 110a to the conductive pattern 124 and to a plate conductor 130. Specifically, each wire 140a has an end which is connected to a plate conductor 130 and an end which is connected to the second pad 111b of the corresponding transistor 110a, thus electrically connecting the plate conductor 130 to the second pad 111b. In the present preferred embodiment, three wires 140a are preferably used for each plate conductor 130. Each wire 140b electrically connects the second pad 111b of the corresponding transistor 110a to the sixth conductive region 124f. Each wire 140c electrically connects the third pad 111a of the corresponding transistor 110a to the sixth conductive region 124f.

The second pad 111b of each transistor 110a is a source pad, through which a large current flows. Therefore, it is preferable to connect the second pad 111b to the corresponding plate conductor 130 by using as many wires as possible, thus to realize a low resistance connection between the second pad 111b and the plate conductor 130.

As the wires 140a, 140b, and 140c, aluminum lines having a diameter of about 0.5 mm may be used, for example. The connection between the wires 140a, 140b, and 140c and the conductive pattern 124 or any transistor 110 is preferably realized by ultrasonic bonding using a wire bonder. However, a conductive line composed of any other material may instead be used with any other connection technique such as melting or crimping. It will be appreciated that the resistance of the wires 140a, 140b, and 140c themselves is preferably low. For example, a conductor which mainly contains (typically about 95% or more of) aluminum is a suitable material for the wires 140a, 140b, and 140c. In the case of using ultrasonic bonding, the wires preferably have a diameter of no more than about 1.0 mm, and more preferably no more than about 0.7 mm, for example, in order to reduce damage to the semiconductor devices.

As described earlier, the terminals a and b are respectively connected to the plus and minus terminals of the battery 103, and the terminals c, d, and e are connected to the motor 102. The gates of the sixth transistors 110 are connected to the gate driving circuit 105 via the sixth conductive region 124f and the connectors 125.

In the power module 101, when a control signal is applied from the gate driving circuit 105 to the gate of each transistor 110, the transistor 110 is turned ON and OFF with a predetermined timing. As a result, the DC current which is being supplied from the battery 103 is converted into a three-phase current, and induced at the terminals c, d, and e. Thus, the motor 102 is driven by the three-phase current. The motor 102 drives driving wheels or other driven members (not shown), thus propelling the transportation apparatus.

Next, referring to FIGS. 4 and 5, an exemplary method of producing the power module 101 will be described. First, the wiring board 120 with the conductive pattern 124 formed thereon is produced. Specifically, a substrate 123 is prepared whose entire insulative surface 122 is covered with a conductive film, and, the conductive pattern 124 is formed on the insulative surface 122 of the substrate 123 preferably via an etching process.

Next, cream solder is applied at predetermined positions by a printing technique or other suitable process, and the transistors 110, the chip resistors 126, the connectors 125, and the plate conductors 130 having insulating layers 131 on the back sides thereof are placed on the cream solder. Each insulating layer 131, which is composed of epoxy resin which can be thermally melted and cured, is previously printed or attached on the back surface of each plate conductor 130. Alternatively, prior to the placement of the plate conductors 130, the insulating layers 131 may be placed in regions of the second conductive region 124b to be occupied by the plate conductors 130.

Thereafter, the wiring board 120 having these elements disposed thereon is introduced into a reflow oven, and heated at a predetermined temperature to melt the solder. At this time, the insulating layers 131 are also melted. By taking the wiring board 120 out of the reflow oven and allowing the wiring board 120 to cool, the transistors 110, the chip resistors 126, the connectors 125, and the insulating layers 131 become soldered to the predetermined regions of the conductive pattern 124. Moreover, the epoxy resin also cures, whereby the plate conductors 130 are affixed to the predetermined positions.

Finally, by using a wire bonder, the pads of the transistors 110 are connected to predetermined regions of the conductive pattern 124 and the plate conductors 130 by aluminum wires, thus forming the wires 140a, 140b, and 140c. Thus, the power module 101 is completed.

In accordance with the power module 101 of various preferred embodiments of the present invention, power semiconductor devices such as transistors are connected to the conductive pattern on the wiring board via wiring elements which are composed of plate conductors and wires. Since the plate conductors have a smaller resistance than that of wires, the use of plate conductors (instead of wires) in certain portions between the conductive pattern and the transistors on the wiring board reduces the resistance of the wiring elements between the conductive pattern and the power semiconductor devices on the wiring board. As a result, the heat generated when a current flows between the conductive pattern and the transistors on the wiring board can be reduced. Moreover, the heat generated in the plate conductors or the heat which is transmitted from the wires to the plate conductors can be dissipated to the wiring board via the insulating layers. As a result, building up of heat in the plate conductors and the wires is also reliably prevented.

Moreover, since the heating associated with the wiring elements between the conductive pattern and the transistors on the wiring board is reduced, the amount of heat which is transmitted to the power semiconductor devices is reduced. As a result, any increase in the temperature of the power semiconductor devices can be reliably prevented. For a given amount of current flowing through the wiring elements, the temperature of the power semiconductor devices during operation can be kept lower than in the case of using conventional wiring elements which are composed only of wires. Therefore, deterioration of the power semiconductor devices can be prevented, and the reliability of the power semiconductor devices can be improved. Alternatively, assuming that the temperature of the power semiconductor device can be permitted to increase to a given temperature, a larger current can be allowed to flow than in the case of conventional wiring elements which are composed only of wires.

Since the portions in which wires are used as the wiring elements are reduced in length, the inductance between the conductive pattern and the power semiconductor devices on the wiring board can be reduced. As a result, the surge voltage which is generated when rapidly switching the power semiconductor devices can be reduced.

The present invention makes it possible to use a wiring board having only a single conductive layer, and consequently, such a wiring board can be produced at a low cost. Since no current flows other than in the conductive pattern defining a conductive layer, even in the case where a metal plate is used as the wiring board in order to obtain increased heat-releasing ability, it is unnecessary to use any particular insulation element between the metal plate and the case (housing), e.g., an insulative film. Therefore, it is possible to effectively utilize the releasing of heat from the wiring board to the exterior (e.g., the case), so that increase in the temperature of the semiconductor devices and the like can be prevented, and the reliability of the semiconductor devices can be improved.

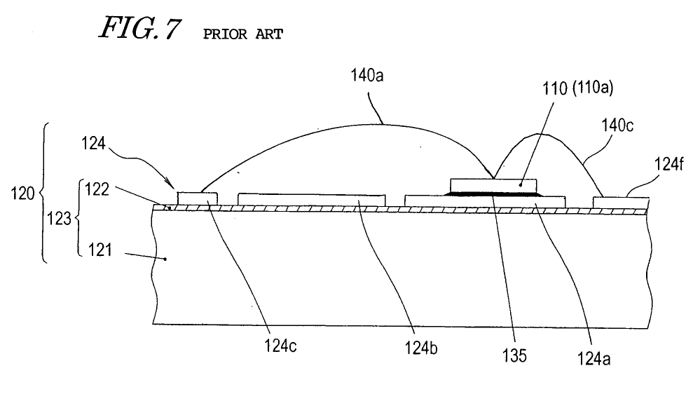

The effects of reduction in resistance and inductance in the power module 101 due to the use of plate conductors will be described with reference to Table 1 below and FIG. 7. FIG. 7 is a cross-sectional view showing a structure in which, as in conventional techniques, a transistor 110a is connected to a third conductive region 124c only via wires 140a, without using plate conductors 130.

TABLE 1

| | |
|---|---|
| Conventional | Present Invention |

Wires

| | | |
|---|---|---|
| Diameter (mm) | 0.5 | 0.5 |
| Length (mm) | 15 | 6 |
| Number of Wires | 3 | 3 |
| Resistance (mO) | 0.7 | 0.28 |
| Inductance (nH) | 10 | 2.8 |

Plate Conductors

| | | |
|---|---|---|
| Thickness (mm) | | 1 |
| Width (mm) | — | 4 |
| Length (mm) | | 9 |
| Resistance (mO) | | 0.04 |
| Inductance (nH) | — | 3.2 |
| Total Resistance (mO) | 0.7 | 0.32 |
| Total Inductance (nH) | 10 | 6.0 |

As shown in FIG. 7, in the conventional technique, the transistors 110a are connected to the conductive pattern 124 (third conductive region 124c) only by wires 140a straddling the second conductive region 124b. This results in the need to elongate the wires 140a, which causes the problem of heating due to resistance of the wires 140a. On the other hand, according to various preferred embodiments of the present invention, as shown in FIG. 5, plate conductors 130 are provided in certain portions between the transistors 110a and the conductive pattern 124 (third conductive region 124c), instead of wires 140a. Therefore, the resistance of the wiring elements between the transistors 110a and the conductive pattern 124 is greatly reduced.

As shown in Table 1, in the conventional wiring elements composed only of wires, three wires composed of aluminum (diameter: 0.5 mm; length: 15 mm) are used, resulting in a resistance of 0.7 m Ω. According to a preferred embodiment of the present invention, although the total length of the wiring elements is the same, the use of the approximately 6 mm-long wires and the approximately 9 mm-long plate conductors results in a resistance of about 0.32 m Q. Thus, it can be seen that the resistance according to a preferred embodiment of the present invention is reduced to about ½ or less as compared to the case of using conventional wiring elements composed only of wires. Assuming that a current of about 100 A flows through such wiring elements, there would be a heat loss of about 7.0 W for the conventional wiring elements, and only about 3.2 W for a preferred embodiment of the present invention.

Moreover, the inductance according to a preferred embodiment of the present invention is reduced to about 6.0 nH, as compared to about 10 nH of the conventional wiring elements. Thus, an approximately 40% reduction in inductance is attained with this preferred embodiment of the present invention.

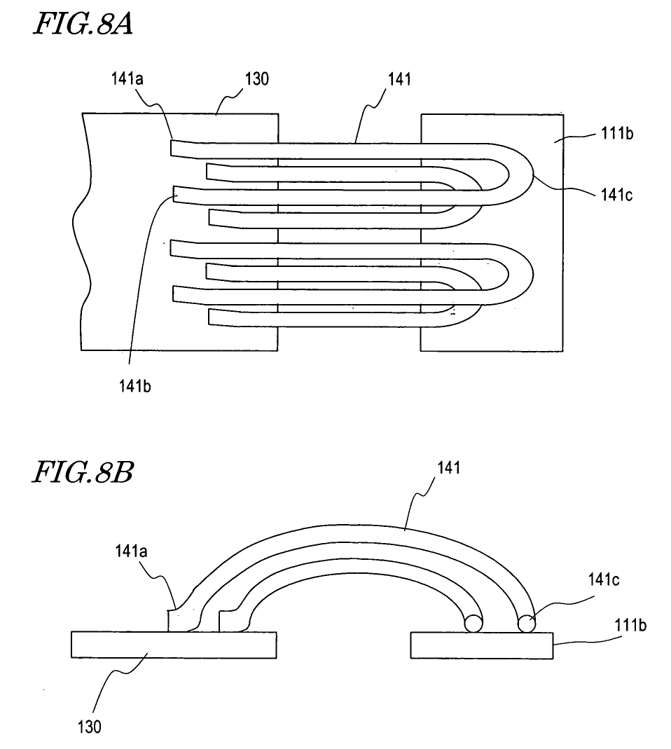

In the above-described preferred embodiment of the present invention, it is assumed that the wire(s) connected to each plate conductor is connected via the same connection mechanism as in the conventional wires. However, a wire structure described below may be used in combination with the above-described preferred embodiment. FIGS. 8A and 8B are a plan view and a cross-sectional view, respectively, showing an exemplary novel wire structure according to a preferred embodiment of the present invention for connecting one end of a plate conductor 130 to the second pad 111b of a transistor 110. As shown in FIGS. 8A and 8B, each wire 141 has ends 141a and 141b which are bonded to a plate conductor 130, as well as an intermediate portion 141c which is bonded to a second pad 111b, thus connecting the plate conductor 130 to the second pad 111b. In other words, taking advantage of the wires 141 being flexible thin lines, each wire 141 is bent at its intermediate portion 141c into what may appear as a U-shaped bundle with two legs, the intermediate portion 141c being bonded to the second pad 111b of the transistor 110.

With this configuration, by forming only one joint (bonding site) on the second pad 111b of the transistor 110, it becomes possible to obtain two wire paths connecting between the plate conductor 130 and the second pad 111b. FIGS. 8A and 8B illustrate an example where four joints are provided on the second pad 111b so as to define eight paths.

With this structure, it is possible to bond more wires than there are joints on a given pad of a semiconductor device (e.g., a transistor). Therefore, at the time of bonding, the damage to be inflicted upon the semiconductor device by the use of ultrasonic waves, or the thermal damage to be inflicted upon the semiconductor device by the use of melting can be reduced. By reducing the number of joints, the amount of time required for wire bonding can be reduced, whereby the production cost can be reduced.

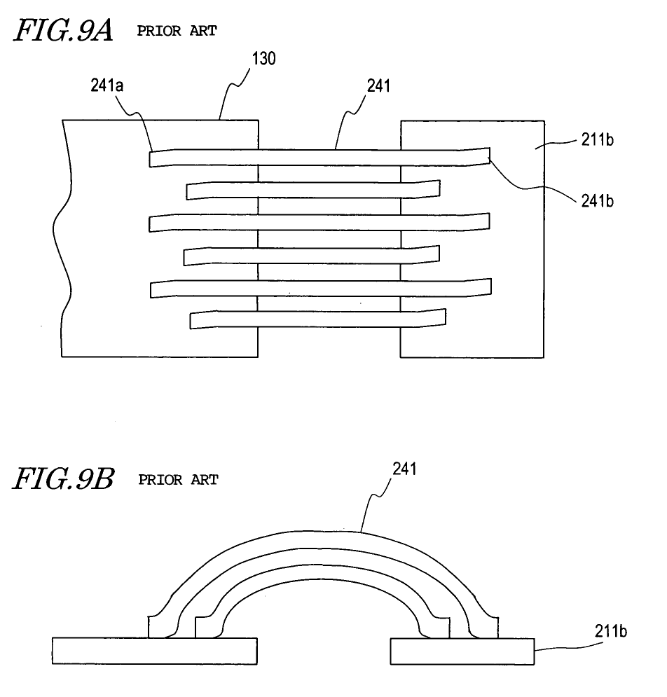

The area of each pad of a semiconductor device is constrained by limits associated with the outer shape of the device. Therefore, even if there is a desire to bond a large number of wires in order to reduce the resistance of the wiring elements, the number of wires that can be bonded is limited by the size of the pad. For comparison, FIGS. 9A and 9B show a wire structure which is formed by a conventional bond technique for connection between a plate conductor 130 and a pad 211b, where the pad 211b has the same size as that of the second pad 111b shown in FIGS. 8A and 8B. In the conventional structure where ends 241a and 241b of each wire 241 are respectively bonded on the plate conductor 130 and the pad 211b, it would only be possible to form six joints, for example, on the pad 211b, thus resulting in only six wires 241, for example. On the other hand, with the structure shown in FIGS. 8A and 8B, two wire paths can be provided for each single joint on the second pad 111b. In other words, the conventional limits on the number of wires (which are associated with the area of each pad of a semiconductor device) are overcome by the structure of preferred embodiments of the present invention, whereby the resistance of the wiring elements can be reduced.

The following procedure may be adopted, for example, to realize the connections as shown in FIGS. 8A and 8B through wire bonding using ultrasonic waves.

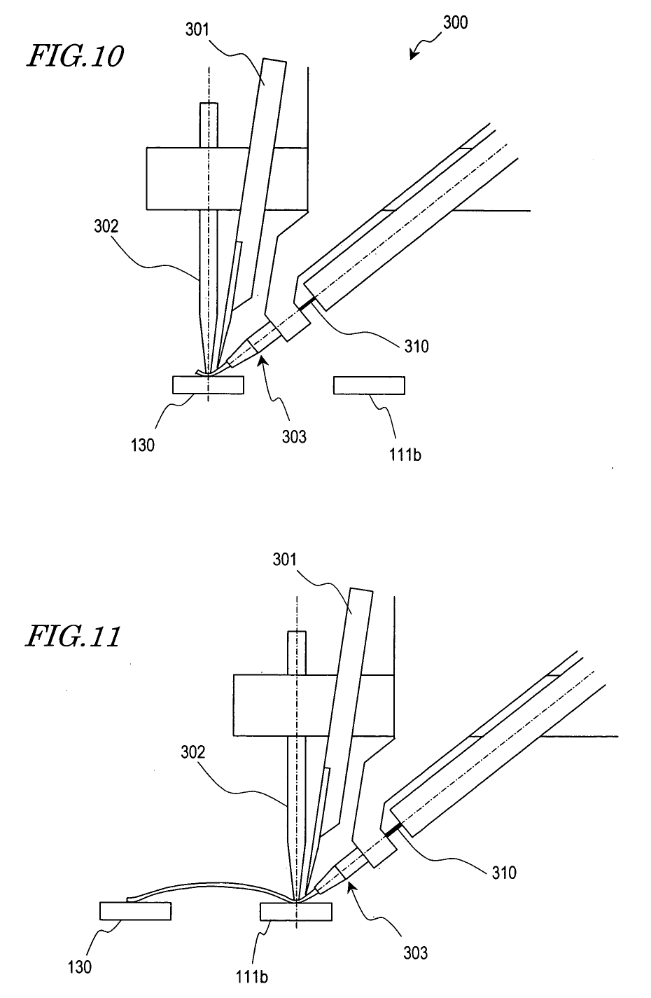

First, as shown in FIG. 10, a tool 302 of a wire bonder is placed on a plate conductor 130, and an end of a wire 310 which is spun out from a wire guide 303 is bonded to the plate conductor 130 by the action of ultrasonic waves which are applied from the tool 302.

Next, as shown in FIG. 11, the tool 302 is moved onto a second pad 111b. Through a similar procedure, the wire 310 is spun out from the wire guide 303, and the wire 310 is bonded to the second pad 111b by the action of ultrasonic waves which are applied from the tool 302. After the bonding, the tool 302 is lifted, and a small portion of the wire 310 is pulled out in the upper direction.

Thereafter, the tool is turned by 180°, and then the tool 302 is moved onto the plate conductor 130. Instead of turning the tool 302, the wiring board itself may be turned. Through such a procedure, the wire can be turned around without applying stress on the joint.

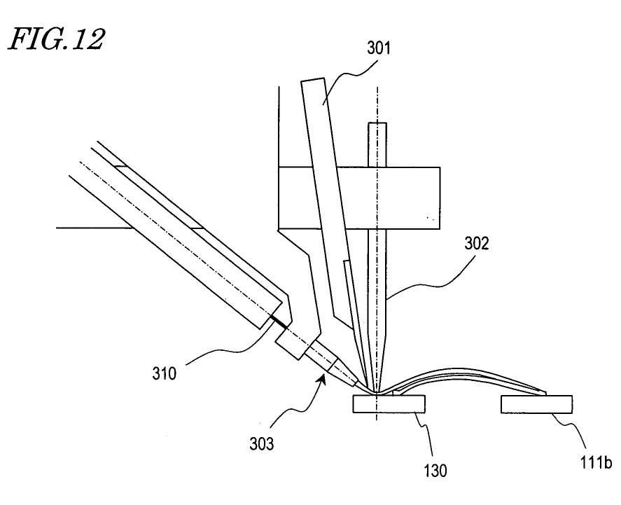

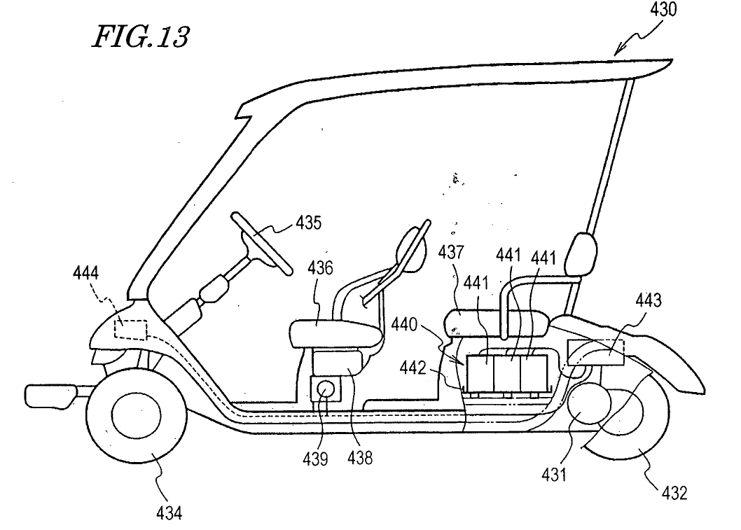

Next, as shown in FIG. 12, after the tool 302 of the wire bonder has been moved onto the plate conductor 130, the wire 310 spun out from the wire guide 303 is bonded to the plate conductor 130 by the action of ultrasonic waves which are applied from the tool 302. Thereafter, the wire 310 is cut via a cutter 301. Thus, the wire connection as shown in FIGS. 8A and 8B is accomplished.

Next, a preferred embodiment of a transportation apparatus according to the present invention will be described.

FIG. 13 shows an electric vehicle 430 according to the present preferred embodiment. The illustrated electric vehicle 430 is preferably a cart which is suitably used for transporting luggage (e.g., golf bags) and people on a golf course, for example. Although FIG. 13 exemplifies a four-wheeled electric vehicle, the transportation apparatus may alternatively be a two-wheeled vehicle such as an electric motorcycle. Other than an electric vehicle, the transportation apparatus may be any transportation apparatus for carrying luggage and people which is run by a motor as a driving or propulsion mechanism.

The electric vehicle 430 of the present preferred embodiment includes a driving motor 431, two rear wheels 432 which are driven by the driving motor 431, and front wheels 434 which are steered manually or automatically. The driving force from the driving motor 431 is transmitted to the rear wheels 432 via a transmission (not shown). The front wheels 434 are steered through manual or automatic operation of a steering wheel 435.

A front seat 436 and a rear seat 437 are provided at the front and rear compartments of the cart. Below the front seat 436, a charging controller 438 and a brake motor 439 are provided. Below the rear seat 437, a driving battery device 440 which defines a power source for the driving motor 431 is provided. The driving battery device 440 preferably includes a total of six batteries 441 which are in series connection (out of which only three batteries 441 mounted on one side of the cart are shown in FIG. 13). The batteries 441 are placed on a keeper 442 with interspaces provided therebetween.

Above the driving motor 431, a controller 443 for drive control is provided. The controller for drive control 443 is connected to the driving battery device 440, the driving motor 431, the brake motor 439, and a steering motor 444 for controlling these devices. The controller for drive control 443 and the driving motor 431 are placed between the two rear wheels 432.

The power module 101 is installed in the interior of the controller for drive control 443, receives a DC current supplied from the battery 440, and converts the DC current into an AC current. The AC current from the power module 101 is supplied to the driving motor 431, the brake motor 439, and the steering motor 444.

According to the present preferred embodiment, by mounting a power module having a high reliability or high power capabilities on an electric vehicle, an electric vehicle is realized which has a high reliability or a high driving performance.

The present invention is applicable to a power module through which a large current flows. In particular, the present invention is suitably used for a transportation apparatus having a motor as its driving mechanism.

While the present invention has been described with respect to preferred embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

This application is based on Japanese Patent Application No. 2004-132778 filed on Apr. 28, 2004, the entire contents of which are hereby incorporated by reference.

1. A power module comprising:
a substrate having an insulative surface and including a conductive pattern located on the insulative surface;
a semiconductor device disposed on the substrate;
a plate conductor provided on the conductive pattern with an insulating layer interposed therebetween; and
a wire arranged to electrically connect the plate conductor and the semiconductor device.

2. The power module according to claim 1, wherein the conductive pattern includes first, second, and third conductive regions; and
a portion of the plate conductor is located above the second conductive region with the insulating layer interposed therebetween, and another portion of the plate conductor is electrically connected to the third conductive region.

3. The power module according to claim 2, wherein the first, second, and third conductive regions are arranged in such a manner that the second conductive region is interposed between the first and third conductive regions.

4. The power module according to claim 3, wherein the semiconductor device has a first and second principal surfaces, and includes a first pad provided on the first principal surface and a second pad provided on the second principal surface;
the semiconductor device is located on the first conductive region;
the first pad of the semiconductor device opposes and is electrically connected to the first conductive region; and
the wire is electrically connected to the second pad.

5. The power module according to claim 4, wherein the other portion of the plate conductor is soldered to the third conductive region, and the first pad of the semiconductor device is soldered to the first conductive region.

6. The power module according to claim 5, wherein the plate conductor is composed mainly of copper, and is surface-treated to have increased solder wettability at least in a region which is soldered to the third conductive region.

7. The power module according to claim 1, wherein the wire is composed mainly of aluminum.

8. The power module according to claim 7, wherein the wire is attached to the second pad and the plate conductor via an ultrasonic wave bond.

9. The power module according to claim 8, wherein the wire is a flexible thin line having two ends and an intermediate portion, the two ends being bonded to the plate conductor, and the intermediate portion being bonded to the second pad.

10. The power module according to claim 9, further comprising a plurality of wires arranged to connect the plate conductor and the second pad.

11. The power module according to claim 1, wherein the semiconductor device is a field-effect transistor.

12. The power module according to claim 11, further comprising a plurality of said semiconductor devices and a plurality of said plate conductors.

13. The power module according to claim 1, wherein the substrate includes a metal substrate and an insulating layer disposed on a surface of the metal substrate.

14. The power module according to claim 1, wherein the wire has first and second ends bonded to the plate conductor and an intermediate portion bonded to a conductive pad to electrically connect the plate conductor and the semiconductor device.

15. The power module according to claim 10, wherein each of the plurality of wires includes first and second ends bonded to the plate conductor and an intermediate portion bonded to the second pad so as to connect the plate conductor and the second pad.

16. An electric transportation apparatus comprising:
the power module according to claim 1; and
a motor electrically connected to the power module.

17. An electric vehicle comprising:
the power module according to claim 1;
a motor electrically connected to the power module;
a battery arranged to supplying power to the power module; and
a wheel to be driven by the motor.

18. A method for producing a power module, the method comprising the steps of:
preparing a substrate having a conductive pattern provided on a surface thereof;
affixing by soldering a semiconductor device onto the substrate, and affixing by soldering a plate conductor onto the conductive pattern with an insulating layer interposed between the plate conductor and the conductive pattern; and
connecting the plate conductor and the semiconductor device via a conductive wire.

19. A method for connecting two conductive regions with a conductive wire, the method comprising the steps of:
bonding a first end of a flexible conductive wire having first and second ends and an intermediate portion interposed between the first and second ends to a first conductive region by ultrasonic waves;
bonding the intermediate portion of the conductive wire to the second conductive region by ultrasonic waves; and
bonding the second end of the conductive wire to the first conductive region by ultrasonic waves.
